(19) United States
(12) Patent Application Publication
(10) Pub. No.: US 2023/0042586 A1
(43) Pub. Date: Feb. 9, 2023

(54) INTERFERENCE LITHOGRAPHY USING REFLECTIVE BASE SURFACES

(71) Applicant: Toyota Motor Engineering & Manufacturing North America, Inc., Plano, TX (US)

(72) Inventors: Shailesh N. Joshi, Ann Arbor, MI (US); Gaurav Singhal, Champaign, IL (US); Paul Vannest Braun, Champaign, IL (US); Danny J. Lohan, Ann Arbor, MI (US); Kai-Wei Lan, Champaign, IL (US)

(73) Assignees: Toyota Motor Engineering & Manufacturing North America, Inc., Plano, TX (US); The Board of Trustees of the University of Illinois, Urbana, IL (US)

(21) Appl. No.: 17/394,812

(22) Filed: Aug. 5, 2021

(51) Int. Cl. G03F 7/00; G02B 1/00; G03F 1/78

(52) U.S. Cl. CPC G03F 7/001; G02B 1/005; G03F 1/78

(57) ABSTRACT

A three-dimensional photonic crystal template on a reflective substrate displays a periodic patterned from multibeam interference lithography with constructive volumes of a cured photoresist composition and destructive volumes that are voids free of mass containing defects and where the reflective substrate is conductive. A method to generate the three-dimensional photonic crystal template includes using at least four laser beams of unequal intensity, oriented such that a dose of light controlled by the irradiation time generates the periodic pattern with a small dose, where the light reflected from the substrate is insufficient to activate a threshold quantity of photoinitiator in the destructive volumes for the formation of any anomalous condensed matter in the intended void volume.

### TECHNICAL FIELD

The present disclosure generally relates to a method to mitigate the effect of surface reflections during holographic lithography of a photoresist.

### BACKGROUND

The background description provided herein is for the purpose of generally presenting the context of the disclosure. Work of the presently named inventors, to the extent it may be described in this background section, as well as aspects of the description that may not otherwise qualify as prior art at the time of filing, are neither expressly nor impliedly admitted as prior art against the present technology.

The formation of a three-dimensional photonic crystal yields a structure where, due to a favorable geometry of voids and mass of high refractive index, photonic band gaps can be prepared where light does not propagate in any direction. These crystals have been developed with the goal of forming enabling devices for optical switching, sensors, filters, wave guides, or any other structure that is functional due to a universally connected structure with percolating pores throughout. These materials have features with dimensions of the nanometer and micrometer scales. A method to produce such materials is by multibeam interference lithography, also called holographic lithography. Multibeam interference lithography does not provide a flexibility and resolution that is exhibited by other techniques, such as electron or ion beam lithography (EBL or IBL), however, superior patterning speed and pattern coherence are observed at scales larger than about 10 nanometers.

In multibeam interference lithography, four laser beams can be used to generate three-dimensional periodicity by the interference pattern of light activated volumes and void volumes. Three-dimensional structures are fabricated in the light activated medium by a photoinitiated polymerization of a photoresist. The polymerization is carried out in a post-patterning baking process, as initiation occurs without significant propagation during the lithographic process at normal ambient room temperatures. Light reflection from a substrate supporting the photoresist can reduce the resolution and quality of the interference pattern that is generated, causing photoinitiation in volumes where direct light is designed to result in destructive interference to ultimately generate a volume void of condensed mass.

Typically, reduction or removal of the reflectance is carried out by coating a substrate with an anti-reflective coating. The coating can be deleterious to a subsequent process required to fabricate a device where the three-dimensional photonic crystal is employed as a template. For example, an electroplating metallization process requires an electrically conductive substrate. To this end, an improved holographic lithography process that gives a high-resolution pattern formed on a reflective substrate is desirable.

### SUMMARY

This section provides a general summary of the disclosure and is not a comprehensive disclosure of its full scope or all features of embodiments.

In various aspects, the present teachings provide a method to form a three-dimensional periodic structure having features of about 0.1 to about 10 microns prepared by a multibeam interference lithography process with a negative photoresist on a reflective substrate, which, after development of the exposed photoresist, forms a periodic pattern of solid constructive volumes and void destructive volumes. This method employs four or more laser beams of non-equal intensity, and the beams' interference allow the periodic structures to be formed on the reflective substrate. The reflective substrate has sufficient electrical conductivity for use of the resulting periodic structure as a three-dimensional photonic crystal template for subsequent processing. The three-dimensional photonic crystal template can be subsequently modified to generate active devices that are supported by the solid template or formed within its voids. Electrodeposition of metals can be performed using the three-dimensional photonic crystal template where the conductive reflective substrate is a portion of an electrode.

In another aspects, the present teachings provide a method to perform multibeam interference lithography with at least four laser beams, where a negative photoresist is patterned on a reflective substrate without anomalies due to undesired mass in the destructive volumes. In one embodiment, a central beam can be delivered perpendicularly to the reflective substrate and a multiplicity of equally spaced beams relative to the central beam can be disposed at an angle of less than about 40° to the central beam. By having a central beam of greater intensity than the other beams, and by using a light dose that is small, reflected light is insufficient to activate sufficient photoinitiator within the direct destructive volumes of a negative photoresist composition to generate defects in a generated three-dimensional photonic crystal.

Further areas of applicability and various methods of enhancing the above coupling technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 shows a drawing of the orientation of four laser beams, C, 1, 2, and 3 for the controlling step in a process for the generation of three-dimensional photonic crystal templates according to one aspect of the present technology.

FIG. 2 is a drawing indicating a projection of normal laser beam C and peripheral laser beams 1 and 3 of FIG. 1 within the photoresist composition where the colinear incident and reflectance of C contrasts with the reflectance of the incident beams 1 and 3 according to one aspect of the present technology.

FIG. 3 is a flow chart of a production method to form a patterned photoresist according to one aspect of the present technology.

FIG. 4A is an example of the irradiation of a structure by laser beams, the structure including a reflective substrate with an SU-8 layer deposited thereon.

FIG. 4B is an example of the structure after irradiation, showing an irradiation-formed pattern of photogenerated acid.

FIG. 4C is an example of the structure after baking, showing a volume of unreacted SU-8 monomer and photoinitiator remaining in a continuous periodic pattern contacting a complementary crosslinked polymer in a continuous periodic pattern.

FIG. 4D is an example of the structure after dissolving of the monomer and non-crosslinked polymer, showing a pattern of connected voids residing within the three-dimensional photonic crystal template of cross-linked polymer from SU-8.

FIGS. 5A and 5B are a drawing of a plane of the photonic crystal parallel to the reflective substrate and perpendicular to the substrate, respectively, with a voids that are isolated in the planes but percolating through the entire photonic crystal via connectivity to adjacent planes, and where the solid portion comprises portions of the volume where photogenerated acid occurs.

FIG. 6 shows a scanning electron micrograph of a SU-8 derived photonic crystal using four-beam interference lithography and a transparent glass substrate and a 0.3 second exposure time.

FIG. 7 shows a scanning electron micrograph of a SU-8 derived photonic crystal using four-beam interference lithography and a reflective silicon substrate and a 0.15 second exposure time.

It should be noted that the figures set forth herein are intended to exemplify the general characteristics of the methods, algorithms, and devices among those of the present technology, for the purpose of the description of certain aspects. These figures may not precisely reflect the characteristics of any given aspect and are not necessarily intended to define or limit specific embodiments within the scope of this technology. Further, certain aspects may incorporate features from a combination of figures.

### DETAILED DESCRIPTION

The present teachings provide a three-dimensional photonic crystal template on a reflective conductive substrate. For purposes of embodiments, a conductive substrate is a non-insulating material with a conductivity greater than deionized water. In various embodiments, the three-dimensional photonic crystal template has a periodic structure without defect features due to an unintended cross-linking initiated by reflected light rays in destructive volumes, which are regions where destructive interference occurs and are intended to be removed upon dissolving a photoresist composition from constructive volumes, which are regions with no destructive interference of light waves during multibeam interference lithography. No antireflective coating is situated between the substrate and the patterned cured photoresist to minimize reflectance, as sufficient conductivity is intended for use of the three-dimensional photonic crystal template for subsequent processing. The three-dimensional photonic crystal template is suitable for preparing periodic porous supported catalysts, metallic heat transfer devices, or other metallic devices, where the fabrication of these devices is facilitated by having an electrically conductive substrate that allows electroplating and other electrolysis processes to be carried out.

The presently disclosed three-dimensional photonic crystal templates on a reflective substrate are generated by an interference lithographic method using four or more laser beams where the beams are of unequal intensity. The periodicity of the three-dimensional photonic crystal template is affected by the angle of incidence of the laser beams relative to each other and the substrate in the lithographic process. Although differing orientations and alignments of beams are possible, in one embodiment, one central beam is situated perpendicular to the substrate supporting the patternable photoresist. The three other peripheral beams are situated about 120° from each other in a periphery to the central beam and directed at an acute angle, generally, but not necessarily, less than about 40° to the central beam, and intersecting with the central beam at an interface of air or inert gas and a planer photoresist surface. The central perpendicular beam can be of greater intensity, for example, about four times the intensity, of the other three beams, either individually or collectively. By using this geometry and a reflective substrate, the dose required for pattern formation is achieved with a very short irradiation period, for example, less than about 0.3 seconds for a 5-watt laser. The laser interference provides a sufficient dose with the short irradiation for initiator generation in a pattern defined by the interference of the laser beams throughout the photoresist. The oriented laser beams define a periodic pattern of constructive volumes without destructive interference of the light waves where photoactivation of the photoinitiator occurs and destructive regions where the irradiation geometry insures destructive light interference to avoid photoinitiation. By employing a limited light dose and the inequal intensities of the beams, the reflected light is of insufficient intensity to allow an insoluble mass to be formed in the destructive volumes where voids are to be formed after development of the photoresist composition. By fixing the laser intensity, modification of the process requires manipulation of only the exposure time.

As detailed herein, the present teachings not only include the method for making periodic photonic crystal templates with few aberrations due to reflected light, but by using a fixed, though not equal, laser intensity for all beams, the fraction of the final three-dimensional photonic crystal templates that are voids is controllable and is inversely proportional to the dose period. As the exposure period is controlled by effectively switching the light on and off, the void portion of the template can be altered as needed to preserve the integrity of the void volume, even during a production run. By appropriate choice of the angle of the laser beams to the substrate, at least a portion of reflected light can be complementary to the incident light for generating a desirable three-dimensional photonic crystal template and unintended photoactivation designed destructive regions can be minimized to the point of no significant anomalies in the pattern.

The three-dimensional photonic crystal templates of the present disclosure can be used as a template for processes that require a sufficiently conductive substrate, such as a silicon substrate, to allow electrodeposition or other processes requiring the substrate to be used as an electrode. In this manner, a relatively large area template with nanometer to micrometer features can be formed with a simple short burst of laser light. The three-dimensional photonic crystal template can be of various negative photoresists, when the initiation of polymerization can be generated photolytically by the laser wavelengths employed. In general, but not necessarily, the polymerization is a living or controlled diffusion polymerization, such as a photo-cationic, photo-anionic, or a photo-generated reversibly stabilized radical polymerization. For example, the negative photoresist can be SU-8, where a multi-epoxy monomer is polymerized via a cationic photo-initiator that is activated by the light projected across the surface and the interference pattern of initiating cations is formed within the glassy photoresist.

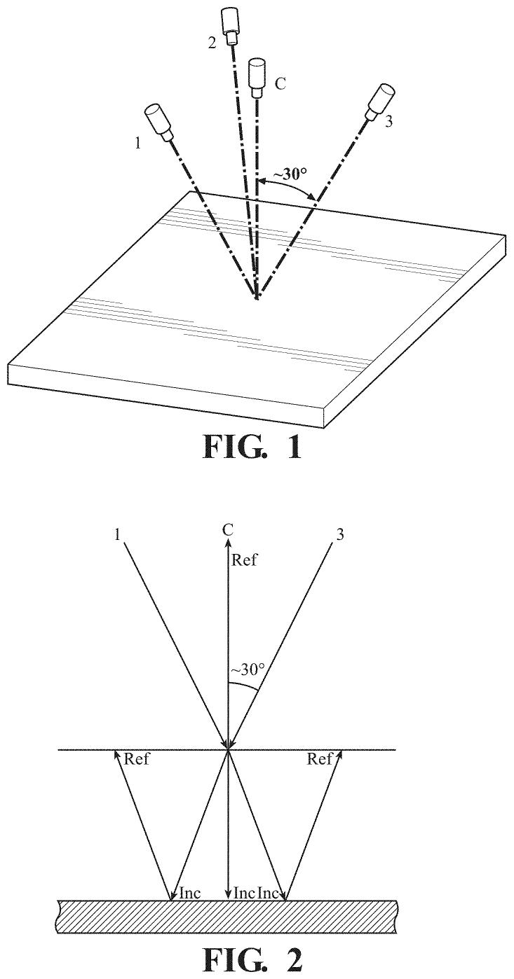

In one aspect of the present technology, the laser beams may be oriented in the manner illustrated in FIG. 1, where the central beam (C) is perpendicular to the substrate surface with three other beams (1, 2, and 3) oriented with an angle of about 30° to beam C, and where beams 1, 2, and 3 are oriented at about 120° to each other. The intensity of beam C is about 3.7 times the intensity of beams 1, 2, and 3, which are of the same intensity. The beams are all in the same phase, being split from a single source beam. As shown in FIG. 2, the path of beam C is such that the incident beam and reflected beam from the reflective substrate are co-linear and provide a nearly doubling of the intensity of the light along beam C's orientation and does not promote a reflection defect with a short exposure. The reflection of incident beams 1, 2, and 3 are of significantly lower intensity, allowing the defect photo-initiated active species to be of insufficient concentration to develop a cross-linked structure at a sufficient rate and degree required to form a defect during a subsequent development step. This orientation and differing beam intensities allow for a full development of the intended interference pattern that defines the three-dimensional photonic crystal template by using a very short beam dose period, for example, but not limited to about 0.15 seconds of exposure. The reflective substrate can be silicon, such as a wafer where the reflectivity is typically below about 30% reflective but can be as much as about 60% reflective depending on the wavelength and smoothness of the surface. Light reflection is generally avoided in interference lithography because it activates polymerization in volumes that are intended to be voids resulting in aberrations in any desired structure formed from the incident light.

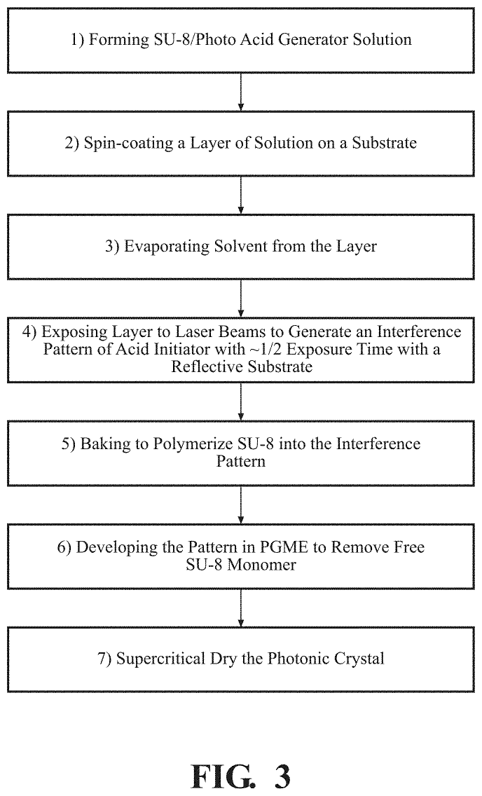

FIG. 3A and FIG. 3B show maps of the top (laser proximal) surface and a cross-section from the top surface to the substrate, respectively, for the intensity of light pattern, and ultimately upon processing, the pattern of solid features and voids in the resulting planes. These periodic patterns of solid features and voids are the result of the constructive and destructive interference of the four laser beams.

In one aspect, the method does not require any modification of an established development protocol for initiation, polymerization, crosslinking, and developing to form the cured photoresist resin. A traditional process for forming and developing a photoresist is outlined in the flow chart provided in FIG. 3, beginning with the formation of an SU-8/photo acid generator solution. The solution is spin-coated and deposited as a layer on a substrate, with the solvent subsequently evaporated. The layer is exposed to laser beams for generation of an interference pattern of acid initiator. As indicated in step 4) of the flow chart, the use of a reflective substrate allows the reduction of the irradiation time to about one half of the time typically used with a transparent substrate to achieve a final photonic crystal with an equivalent structure. The method proceeds to a baking step to polymerize an SU-8 structure in the interference pattern. In various aspects, the pattern is developed in PGME to remove free SU-8 monomer. For example, the pattern is subsequently developed by dissolving unpolymerized volumes of the structure. This may be followed with supercritical drying steps to ultimately yield the photonic crystal.

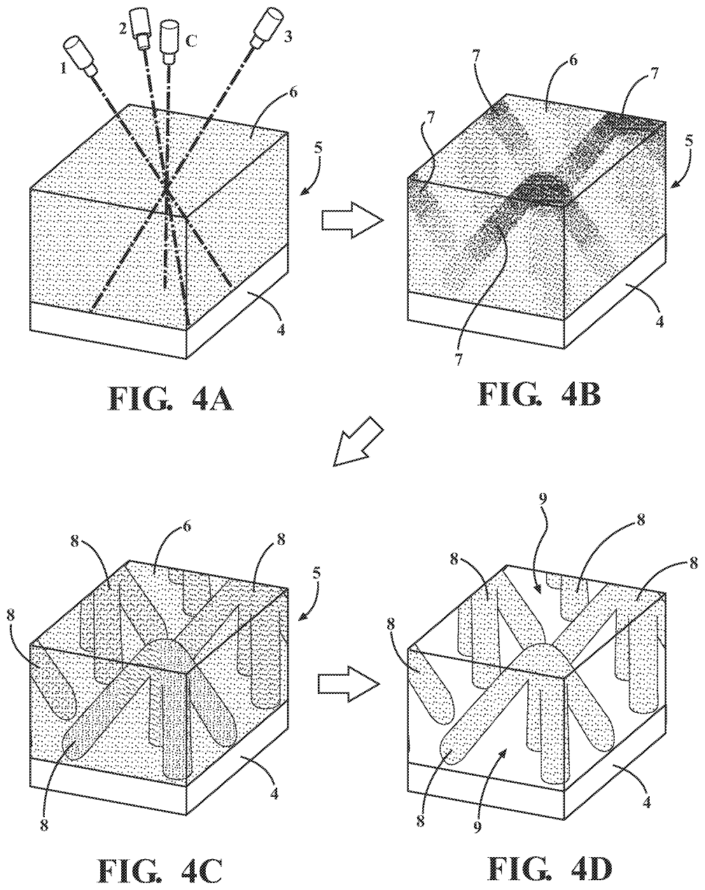

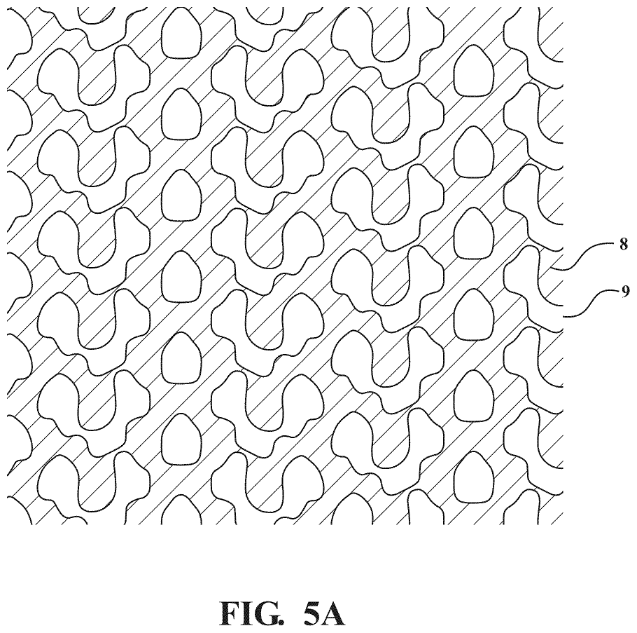

Portions of the process of FIG. 3 are graphically illustrated in FIGS. 4A-4D. FIGS. 4A-4D illustrate structure determining steps, and the outcome after exposing a homogeneously dispersed photoinitiator in a polyfunctional monomer to form a pattern of photogenerated acid that, upon baking, forms a pattern of solid cross-linked polymer by acid initiation, and yields the photonic crystal by dissolution of unreacted monomer and photoinitiator.

The exemplary structure of FIG. 4A includes a reflective substrate 4 with an SU-8 layer 5 deposited thereon. The SU-8 layer 5 includes a dispersed or dissolved photoinitiator 6 in order to provide a photo curable resin layer. Notably, FIGS. 4A-4D illustrate the formation of a portion of a layer of the photonic crystal along the z-axis, and it should be appreciated that this pattern may be displaced in the x-y plane, repeated in an overlapping manner, and displaced along the z-axis multiple times to form the entire photonic crystal, depending only upon the orientations of the laser beams and thickness of the photo curable resin layer. FIG. 4A begins the patterning process and provides an exemplary illustration of the irradiation by laser beams 1, 2, 3, and C on the surface of the SU-8 layer 5. The relative thickness of deposited SU-8 layer 5 and substrate 4 in FIGS. 4A-4D are not intended to limit the thickness of either layer, or their relative thickness.

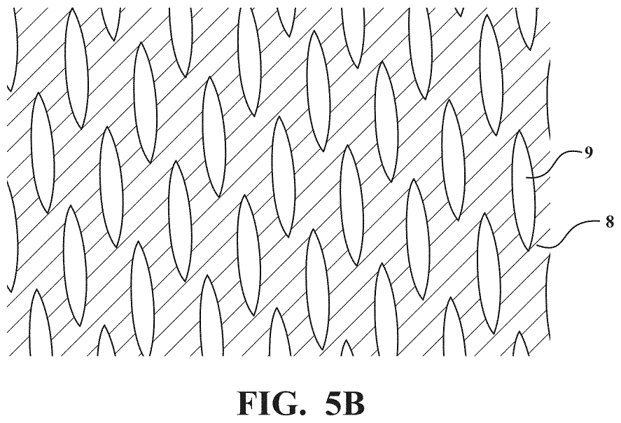

As shown in FIG. 4B, the irradiation forms a pattern of photogenerated acid 7 generally being leveled by reaction with an epoxy group of the SU-8 as an initiated, but not propagating in the glassy SU-8. The pattern of photogenerated acid 7 shown in FIG. 4B is exemplary in nature and may begin with a gradient-like pattern with areas of different intensity, since the formation of photogenerated acid 7 generally occurs at locations where there is constructive interference of the beams, and the beam orientation may vary. FIG. 5A shows a plane parallel to the substrate and irradiated surface where the solid portion of the photonic crystal of crosslinked polymer 8 is that which ultimately forms from the photogenerated acid residing in each plane. The pattern is periodic and dependent upon the orientation of the laser beams. FIG. 5B shows a plane perpendicular to the substrate and irradiated surface where the solid portion of the photonic crystal is that which ultimately forms from the photogenerated acid residing in each plane the voids 9 in each plane percolating in three dimensions through the entire photonic crystal via connectivity of adjacent planes.

The post irradiation processing is represented by the transition of FIG. 4B to FIG. 4C, and includes baking the exposed substrate and photoresist composition to a temperature of less than about 90° C. but more than about 75° C., such as about 85° C. Because the photogenerated initiator photolytically decomposes to, for example, a Lewis acid 7 that adds to the polymerizable functionality of the photoresist, for example, an epoxy functionality of SU-8, polymerization of the multifunctional monomer and crosslinking occur to form a solid mass of crosslinked polymer 8 filled constructive volumes of the templates. Temperatures greater than the desired temperature result in polymerization beyond the constructive volume, and temperatures less than the desired temperature do not permit significant polymerization in the glassy film. The time for post baking depends on the temperature employed, where higher temperatures require less time. After the baking and post baking, a volume of unreacted SU-8 monomer 5 and photoinitiator 6 remains in a continuous periodic pattern contacting a complementary a crosslinked polymer 8 continuous periodic pattern, as shown in FIG. 4C.

After baking, development continues with the dissolving of the monomer and non-crosslinked polymer in the destructive volumes that will generate the voids of the three-dimensional photonic crystal template. As shown in FIG. 4D, this results in a pattern of connected voids 9 residing within the three-dimensional photonic crystal template of cross-linked polymer 8 from SU-8. The dissolving of the non-crosslinked polymer in the destructive volumes will generate the voids of the three-dimensional photonic crystal template. As active centers remain in the cross-linked volumes, the temperature and diffusion of photoresist solution from the developing three-dimensional photonic crystal template are set for an optimal generation of the template. The solvent can be propylene glycol monomethyl ether acetate (PGMEA) or any other solvent such as acetone, cyclopentanone, and tetrahydrofuran. These solvents swell the crosslinked SU-8 resin and, for example, PGMEA can be desorbed to a large extent by placing the three-dimensional photonic crystal template in isopropanol.

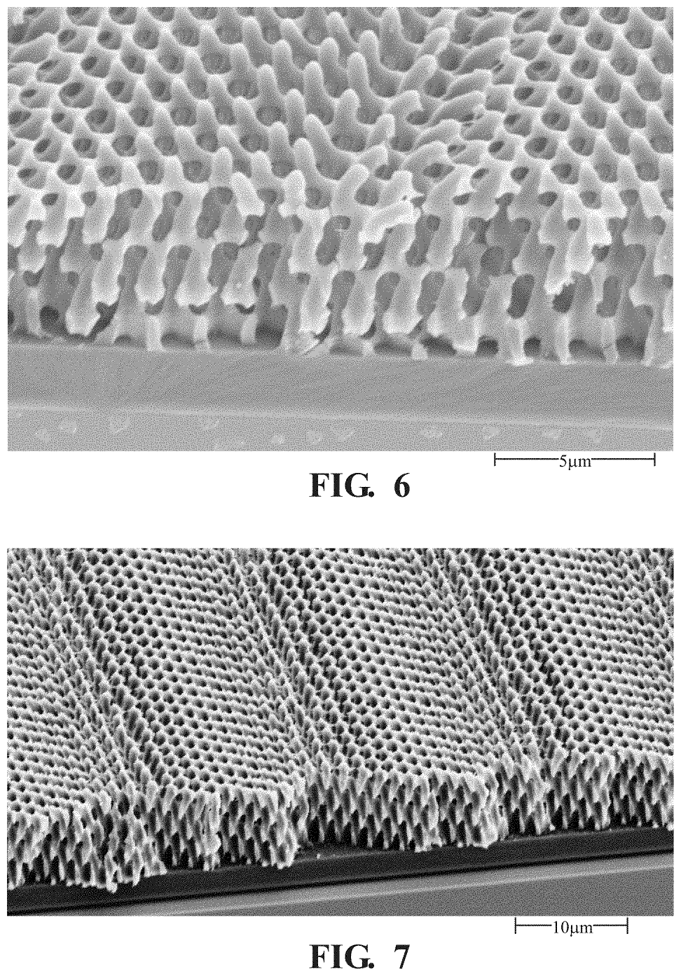

As shown in FIG. 6 and FIG. 7, for a primarily transparent glass substrate and a primarily reflective silicon substrate, respectively, a similar three-dimensional photonic crystal template is generated using an exposure time for the reflective substrate that is about half that used with the transparent substrate.

In the development of the polymer, which further effects the dissolving of the unpolymerized or insufficiently polymerized regions, diffusion rates of the generated active species and propagation rates of the photoresist polymer must be considered. As the degrees of initiation and propagation affect the diffusing species structures, controlling the three-dimensional photonic crystal template structure becomes a complicated process where a viable window to generate the desired structure is easily missed and where small difference in any of time, temperature, and concentration can promote a loss of control required to avoid defect structures. The control of the dosing rate has little error associated with it, as control is exclusively of the amount of initiator generated, particularly with photoinitiators with a high quantum yield, such as, but not limited to, iron-arene salts, such as, cyclopentadienyl(fluorene) iron (III) hexafluorophosphate as a cationic initiator. Photoinitiators that do not act as thermal initiators at temperatures employed for deposition on the substrate or baking during development are advantageous. Other iron-arene salts that can be used include Irgacure 261, [Cp-Fe-Naph]PF₆, CFC, and CFA. Other photoinitiators include diaryliodonium salts and triarylsulfonium salts. The anion coupled to the cation of these photoinitiators can be, but are not limited to, triflate, tosylate, PF₆⁻, SbF₆⁻, and BF₄⁻. A photosensitizer can be included with the photoinitiator. Useful photosensitizers include DIEF, RBAX, TIHF, Acridine Orange, and Erythrosin B. In this manner, the method is implemented by fine control of only one variable, the photonic dose, which can be controlled by the irradiation period, and does not require modification of the development steps where complicated multiple processes occur to define the resin volumes and void volumes.

To avoid structural collapse of the voids during a final drying of the three-dimensional photonic crystal template due to surface tension effects, drying can be carried out using supercritical CO₂ where the liquid-vapor interface is beyond the critical point. The wet three-dimensional photonic crystal template is placed in liquid CO₂ followed by heating past the critical point and releasing the pressure until ambient pressure and temperature is achieved. The resulting three-dimensional photonic crystal template is isolated with distinct constructive volumes of cross-linked photoresist polymer and destructive volumes void of condensed matter.

Modification of the irradiation profile during the formation of the three-dimensional photonic crystal template or by decorating the deposited photoresist surface with reflective or absorbing particles allows the formation of uniform, patterned or gradient periodic structures along any axis and bias the proportion of void volume in the template. This permits the formation of a metal matrix device that displays the negative of the template, where the void volumes result in the metal features and the resin features of the template generate the voids of the metal matrix upon degradation.

The resulting polymeric three-dimensional photonic crystal template is one that, due to a substrate with sufficient conductivity, can be used to fill the voids with a metal or other material that can be deposited by an electrodeposition process. In this manner, the avoidance of defects is critical to assure that the necessary percolation of voids through the template allows the growth throughout the entire template formed from the photoresist layer. Removal of the template allows development of a metallic device, where the positive features of the device are formed in the voids in the template. Other devices, such as a high surface area catalytic supports, can employ the three-dimensional photonic crystal template as a scaffold where a catalyst layer is deposited on the template.

Methods

A diode pump solid state laser, Verdi 5W (Coherent Inc.), a frequency doubled Nd:YVO₄ laser, was used at 532 nm for multi-beam interference lithograph. The Verdi 5W laser has a maximum power of 5.5 W and a beam diameter of 2.25 mm with the beam expanded to as much as 9 mm using a spatial filter and sub-second exposure times. The optical platform employed a rigid table-top (Newport RS-4000) and pneumatic isolators (Newport I-2000) for vibration dampening. The beam was split into four beams and arranged by the mirrors into the umbrella geometry shown in FIG. 1. The power ratio of the beams was controlled by a polarizing cube beam splitter with a half waveplate situated before the splitter and additional half and quarter waveplates for adjusting the side and central beams, respectively, to yield a 3.7 to 1 intensity ratio of the central and side beams where the side beams are aligned at about a 30° angle to the central beam.

The photoresist composition was SU-8, on average an octafunctional monomer, with cyclopentadienyl(fluorene) iron (III) hexafluorophosphate as photoinitiator and deposited as a solution in cyclopentanone and spin-coated on a silicon wafer. Solvent evaporation from the photoresist composition was carried out on a hot plate to a temperature of about 65° C. for ten minutes and about 95° C. for twenty minutes. After cooling to room temperature, exposure was restricted to 0.15 seconds using an electric shutter. After exposure, development was started with a bake at about 85° C. for twenty minutes. After cooling to room temperature, PGMEA was used with gentle stirring to dissolve the destructive volumes and form the periodic structure of the three-dimensional photonic crystal template. Immersion of the template into isopropanol resulted in the extraction of residual PGMEA from the cured SU-8 resin. Supercritical drying was carried out by immersing the isopropanol wet SU-8 resin on the Si wafer in liquid CO₂ using a critical point dryer (Samdri 790) at about 0° C. and slowly heating through the critical point followed by slowly releasing the pressure to ambient and cooling to ambient temperature, which yielded the three-dimensional photonic crystal template on the Si wafer, as shown in FIG. 6.

The preceding description is merely illustrative in nature and is in no way intended to limit the disclosure, its application, or uses. As used herein, the phrase at least one of A, B, and C should be construed to mean a logical (A or B or C), using a non-exclusive logical “or.” It should be understood that the various steps within a method may be executed in different order without altering the principles of the present disclosure. Disclosure of ranges includes disclosure of all ranges and subdivided ranges within the entire range.

The headings (such as “Background” and “Summary”) and sub-headings used herein are intended only for general organization of topics within the present disclosure, and are not intended to limit the disclosure of the technology or any aspect thereof. The recitation of multiple embodiments having stated features is not intended to exclude other embodiments having additional features, or other embodiments incorporating different combinations of the stated features.

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that an embodiment can or may comprise certain elements or features does not exclude other embodiments of the present technology that do not contain those elements or features.

As used herein, the term “about” includes exactly the term or number that it modifies and slight variations therefrom. “Slight variations therefrom” can include within 15 degrees/percent/units or less, within 14 degrees/percent/units or less, within 13 degrees/percent/units or less, within 12 degrees/percent/units or less, within 11 degrees/percent/units or less, within 10 degrees/percent/units or less, within 9 degrees/percent/units or less, within 8 degrees/percent/units or less, within 7 degrees/percent/units or less, within 6 degrees/percent/units or less, within 5 degrees/percent/units or less, within 4 degrees/percent/units or less, within 3 degrees/percent/units or less, within 2 degrees/percent/units or less, or within 1 degree/percent/unit or less. In some instances, “about” can include being within normal manufacturing tolerances.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one aspect, or various aspects means that a particular feature, structure, or characteristic described in connection with an embodiment or particular system is included in at least one embodiment or aspect. The appearances of the phrase “in one aspect” (or variations thereof) are not necessarily referring to the same aspect or embodiment. It should be also understood that the various method steps discussed herein do not have to be carried out in the same order as depicted, and not each method step is required in each aspect or embodiment.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations should not be regarded as a departure from the disclosure, and all such modifications are intended to be included within the scope of the disclosure.

What is claimed is:

1. A method for generating a three-dimensional photonic crystal template on a reflective substrate, comprising:
depositing a photoresist composition comprising a photo-initiator homogeneously distributed throughout a polymerizable photoresist on a reflective substrate that is conductive;
irradiating the photoresist composition with at least four laser beams using a multibeam interference lithograph system for a duration of less than about 0.3 seconds to form an exposed photoresist composition, comprising an activated photoinitiator residing in a constructive volume of a periodic interference pattern and a destructive volume absent the activated photoinitiator;
baking the exposed photoresist composition to form a periodic structure comprising a gelled photoresist portion in the constructive volume undergoing polymerization and crosslinking, and an un-gelled photoresist portion in a destructive volume;
dissolving the destructive volume with a solvent to form an un-gelled photoresist solution; and
removing the un-gelled photoresist solution to yield the three-dimensional photonic crystal template.

2. The method for generating a three-dimensional photonic crystal template according to claim 1, further comprising drying the three-dimensional photonic crystal template of any residual solvent in the three-dimensional crystal template.

3. The method for generating a three-dimensional photonic crystal template according to claim 2, wherein drying is supercritical drying using CO₂.

4. The method for generating a three-dimensional photonic crystal template according to claim 1, wherein the at least four laser beams comprise a central laser beam oriented perpendicularly to the reflective substrate and a multiplicity of peripheral laser beams equally separated from the central laser beam and equally separated from each other, wherein the peripheral laser beams are at an angle of less than about 40 degrees from the central laser beam.

5. The method for generating a three-dimensional photonic crystal template according to claim 4, wherein an intensity of the central laser beam is greater than an intensity of the peripheral laser beams individually.

6. The method for generating a three-dimensional photonic crystal template according to claim 4, wherein an intensity of the central laser beam is greater than an intensity of the peripheral laser beams collectively.

7. The method for generating a three-dimensional photonic crystal template according to claim 4, wherein the central laser beam has an intensity of about four times an intensity of one of the peripheral laser beams, and wherein the multiplicity of peripheral laser beams comprises three peripheral laser beams.

8. The method for generating a three-dimensional photonic crystal template according to claim 1, wherein the photoresist composition comprises: a cationic polymerizable photoresist and the photo-initiator is a cationic photoinitiator; an anionic polymerizable photoresist and the photo-initiator is an anionic photoinitiator; or a radical polymerizable photoresist and the photo-initiator is a radical photoinitiator comprising a reversibly stabilizing additive.

9. The method for generating a three-dimensional photonic crystal template according to claim 8, wherein the cationic polymerizable photoresist is SU-8.

10. The method for generating a three-dimensional photonic crystal template according to claim 8, wherein the cationic photoinitiator is cyclopentadienyl(fluorene) iron (III) hexafluorophosphate.

11. The method for generating a three-dimensional photonic crystal template according to claim 1, wherein the reflective substrate is silicon.

12. The method for generating a three-dimensional photonic crystal template according to claim 1, wherein the solvent is propylene glycol monomethyl ether acetate (PGMEA).

13. A three-dimensional photonic crystal template on a reflective substrate comprising a periodic patterned cured photoresist composition comprising a periodic pattern defined by a multibeam interference lithography process that is free of unintended mass in a destructive volume of a multiplicity of periodic voids, and where the reflective substrate is conductive.

14. The three-dimensional photonic crystal template on a reflective substrate according to claim 13, wherein the reflective substrate is a silicon wafer.

15. The three-dimensional photonic crystal template on a reflective substrate according to claim 13, wherein the periodic patterned cured photoresist composition comprises a polymerized photoresist with a residual photoinitiator.

16. The three-dimensional photonic crystal template on a reflective substrate according to claim 15, wherein the polymerized photoresist is polymerized SU-8 and the residual photoinitiator is cyclopentadienyl(fluorene) iron (III) hexafluorophosphate.
